(19) United States
(12) Patent Application Publication
(10) Pub. No.: US 2022/0366720 A1
(43) Pub. Date: Nov. 17, 2022

(54) BIOMETRIC AUTHENTICATION DEVICE

(71) Applicant: Japan Display Inc., Tokyo (JP)

(72) Inventor: Atsunori OYAMA, Tokyo (JP)

(73) Assignee: Japan Display Inc., Tokyo (JP)

(21) Appl. No.: 17/742,431

(22) Filed: May 12, 2022

(30) Foreign Application Priority Data
May 12, 2021 (JP) 2021-081110

(51) Int. Cl. G06V 40/13; H01L 27/30; H01L 51/00; G06V 40/145; G06V 40/10

(52) U.S. Cl. CPC G06V 40/1318; H01L 27/307; H01L 51/0097; G06V 40/145; G06V 40/15

(57) ABSTRACT

According to one embodiment, a biometric authentication device includes a resin substrate, an optical sensor and an illumination device. The resin substrate has flexibility. The optical sensor is disposed on the resin substrate. The illumination device is disposed on the resin substrate. The optical sensor and the illumination device are disposed on the resin substrate so as to face each other with a detection target interposed therebetween when the biometric authentication device is mounted on the detection target. The optical sensor detects light emitted from the illumination device and transmitted through the detection target.

### CROSS-REFERENCE TO RELATED APPLICATIONS

This application is based upon and claims the benefit of priority from Japanese Patent Application No. 2021-081110, filed May 12, 2021, the entire contents of which are incorporated herein by reference.

### FIELD

Embodiments described herein relate generally to a biometric authentication device.

### BACKGROUND

In recent years, an optical biometric authentication device has been known as a biometric authentication device used for personal authentication or the like. As such an optical biometric authentication device, a configuration in which an optical sensor and an illumination device are provided on separate substrates is known, but such a configuration has a problem that a device scale is large. For this reason, downsizing of an optical biometric authentication device is desired.

### BRIEF DESCRIPTION OF THE DRAWINGS

FIG. 1 is a schematic diagram illustrating a schematic configuration of a biometric authentication device according to a first embodiment.

FIG. 2 is a plan view illustrating an example of an arrangement layout of a sensor and an illumination device included in the biometric authentication device according to the embodiment.

FIG. 3 is a cross-sectional view illustrating a cross section of the biometric authentication device taken along line A-B illustrated in FIG. 2.

FIG. 4 is a plan view schematically illustrating a configuration of sensors included in the biometric authentication device according to the embodiment.

FIG. 5 is a block diagram illustrating a configuration example of a sensor included in the biometric authentication device according to the embodiment.

FIG. 6 is a circuit diagram illustrating a sensor included in the biometric authentication device according to the embodiment.

FIG. 7 is a circuit diagram illustrating a plurality of first pixels included in a sensor included in the biometric authentication device according to the embodiment.

FIG. 8 is a plan view schematically illustrating a configuration of an illumination device included in the biometric authentication device according to the embodiment.

FIG. 9 is a plan view illustrating a shape of a base disposed in a conductive line region according to the same embodiment.

FIG. 10 is a schematic diagram illustrating a schematic configuration of a biometric authentication device according to a second embodiment.

FIG. 11 is a plan view illustrating an example of an arrangement layout of a sensor and an illumination device included in the biometric authentication device according to the embodiment.

### DETAILED DESCRIPTION

In general, according to one embodiment, a biometric authentication device comprises a resin substrate, an optical sensor and an illumination device. The resin substrate has flexibility. The optical sensor is disposed on the resin substrate. The illumination device is disposed on the resin substrate. The optical sensor and the illumination device are disposed on the resin substrate so as to face each other with a detection target interposed therebetween when the biometric authentication device is mounted on the detection target. The optical sensor detects light emitted from the illumination device and transmitted through the detection target.

According to another embodiment, a biometric authentication device comprises a resin substrate, an optical sensor and an illumination device. The resin substrate has flexibility. The optical sensor is disposed on the resin substrate. The illumination device is disposed on the resin substrate. The optical sensor and the illumination device are disposed on the resin substrate so as not to overlap each other in planar view. The illumination device is disposed on the resin substrate so as to surround the optical sensor. The optical sensor detects light emitted from the illumination device and reflected by a detection target.

Embodiments will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same elements as those described in connection with preceding drawings are denoted by like reference numerals, and a detailed description thereof is omitted unless otherwise necessary.

To make the descriptions easily understandable ad needed, drawings illustrate X axis, Y axis and Z axis orthogonal to each other. A direction along the X direction is called a first direction X, a direction along the Y direction is called a second direction X and a direction along the Z direction is called a third direction X. A plane defined by the X axis and Y axis is called an X-Y plane, and a plane defined by the X axis and Z axis is called an X-Z plane. Viewing towards the X-Y plane is called a planer view.

### First Embodiment

FIG. 1 is a schematic diagram illustrating a schematic configuration of a biometric authentication device 1 according to a first embodiment. As illustrated in FIG. 1, the biometric authentication device 1 is used by being wound around a finger Fg, for example. The biometric authentication device 1 includes a sensor 2 (optical sensor) and an illumination device 3 disposed on the same substrate, and the sensor 2 and the illumination device 3 are disposed to face each other with the finger Fg interposed therebetween.

The light emitted from the illumination device 3 is transmitted through the finger Fg and detected by the sensor 2. The sensor 2 is a transmissive type optical sensor, and can detect biological information of the finger Fg by detecting light transmitted through the finger Fg. The biological information is, for example, a fingerprint, a blood vessel image (vein pattern) of a vein or the like, a pulse, a pulse wave, a blood state (blood oxygen concentration or the like), or the like. The color of the light emitted from the illumination device 3 may vary depending on the detection target. For example, in the case of fingerprint detection, the illumination device 3 can emit visible light (for example, blue or green) light, and in the case of vein detection, the illumination device 3 can emit infrared light.

Although FIG. 1 illustrates the case where the illumination device 3 is disposed on the upper face side (nail side) of the finger Fg and the sensor 2 is disposed on the lower face side (ventral side) of the finger Fg, the present invention is not limited thereto, and the sensor 2 may be disposed on the upper face side of the finger Fg and the illumination device 3 may be disposed on the lower face side of the finger Fg.

In the present embodiment, it is assumed that the detection target is the finger Fg, but the detection target is not limited thereto, and any part that can be sandwiched between the sensor 2 and the illumination device 3 can be the detection target.

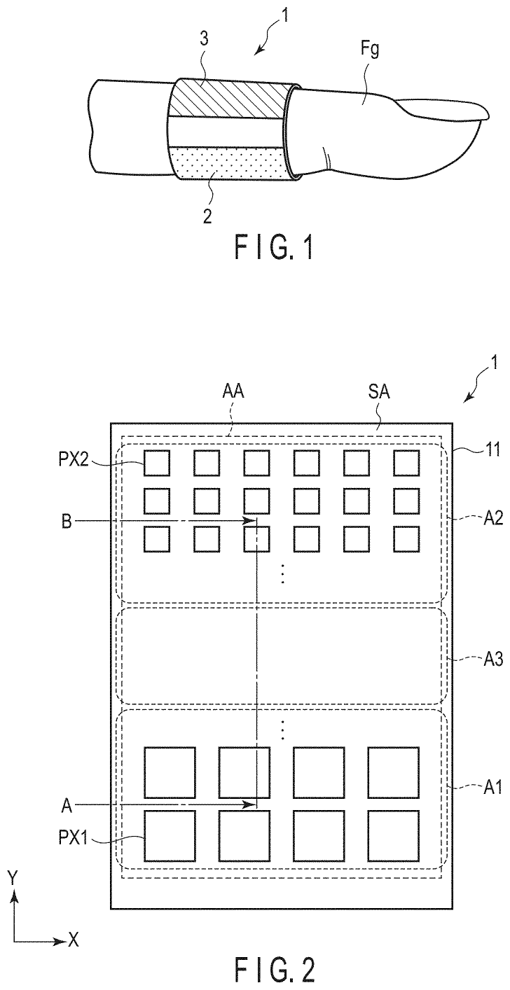

FIG. 2 is a plan view illustrating an example of an arrangement layout of the sensor 2 and the illumination device 3 included in the biometric authentication device 1. As illustrated in FIG. 2, the biometric authentication device 1 includes a base 11, and a detection region AA and a peripheral region SA provided on the base 11. The detection region AA includes a light receiving region A1 (first region), a light emitting region A2 (second region), and a conductive line region A3 (third region). The regions A1, A2, and A3 included in the detection region AA do not overlap each other in planar view.

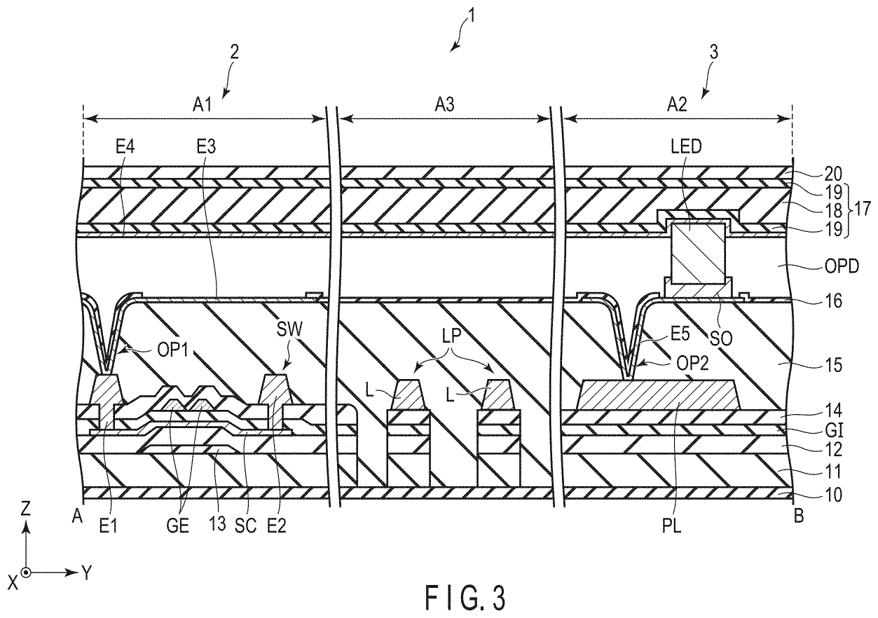

The light receiving region A1 is a region in which a plurality of first pixels PX1 constituting the sensor 2 is provided. The first pixels PX1 are disposed on the base 11. The first pixel PX1 may be referred to as a sensor pixel or an imaging pixel. The plurality of first pixels PX1 is disposed in a matrix in the first direction X and the second direction Y in the light receiving region A1. As will be described in detail later, an organic photoreceiver OPD (see FIG. 3) is provided in each of the plurality of first pixels PX1. The organic photoreceiver OPD receives light emitted from the illumination device 3 and transmitted through the finger Fg to be detected to output an electrical signal corresponding to the amount of received light. The first pixel PX1 may be provided with a positive intrinsic negative (PIN) photodiode instead of the organic photoreceiver OPD.

The light emitting region A2 is a region in which a plurality of second pixels PX2 constituting the illumination device 3 is provided. The second pixels PX2 are disposed on the base 11. The plurality of second pixels PX2 is disposed in a matrix in the first direction X and the second direction Y in the light emitting region A2. As will be described in detail later, a light emitting element LED (see FIG. 3) is provided in each of the plurality of second pixels PX2. The light emitting element LED is, for example, a micro LED or a mini LED, and irradiates the finger Fg to be detected with light.

The number and size of the first pixels PX1 each including the organic photoreceiver OPD and the number and size of the second pixels PX2 each including the light emitting element LED may be different from each other as illustrated in FIG. 2. As an example, the number and size of second pixels PX2 are desirably defined such that one first pixel PX1 is irradiated with light having the amount of light of about 0.1 μW to 1 μW.

The conductive line region A3 is a region interposed between the light receiving region A1 and the light emitting region A2. In the conductive line region A3, the first pixel PX1 and the second pixel PX2 are not disposed. That is, in the conductive line region A3, various elements, various driver circuits described later, and the like are not disposed. In the conductive line region A3, various conductive lines connected to the first pixel PX1 and the second pixel PX2 are provided.

The peripheral region SA is a region outside the detection region AA, and various driver circuits and the like connected to the first pixel PX1 and the second pixel PX2 are disposed.

FIG. 3 is a cross-sectional view illustrating a cross section of the biometric authentication device 1 taken along line A-B illustrated in FIG. 2. Hereinafter, first, a cross-sectional structure of the biometric authentication device 1 (sensor 2) in the light receiving region A1 will be described.

As illustrated in FIG. 3, the biometric authentication device 1 includes the base 11 disposed on a sheet-like support body 10. The base 11 may be any substrate as long as it can withstand the processing temperature during the TFT process, and a glass substrate such as quartz or alkali-free glass, or a resin substrate such as polyimide can be mainly used. The resin substrate has flexibility, and can constitute the sheet-like biometric authentication device 1. For this reason, in the present embodiment, it is assumed that the base 11 is a resin substrate. The resin substrate is not limited to polyimide, and other resin materials may be used.

An undercoat layer 12 having a three-layer stacked structure is provided on the base 11. Although not illustrated in detail, the undercoat layer 12 has a lowermost layer formed of silicon oxide (SiO2), a middle layer formed of silicon nitride (SiN), and an uppermost layer formed of silicon oxide (SiO2). The lowermost layer is provided for improving adherence with the base 11. The intermediate layer is provided as a block film for moisture and impurities from the outside. The uppermost layer is provided as a block film that prevents hydrogen atoms contained in the middle layer from diffusing to the semiconductor layer SC described later.

The undercoat layer 12 is not limited to this structure. The undercoat layer 12 may be further stacked, or may have a single-layer structure or a two-layer structure. For example, when the base 11 is a glass substrate, a silicon nitride film may be directly formed on the base 11 because the silicon nitride film has relatively good adherence.

A light shielding film 13 is disposed on the base 11. The position of the light shielding film 13 is adjusted to a position where a TFT is to be formed later. The light shielding film 13 may be formed of a material having a light shielding property, such as a metal material or a black material. According to such a light shielding film 13, since it is possible to suppress entry of light into the channel back face of the TFT, it is possible to suppress a change in TFT characteristics caused by light that can be incident from the base 11 side. Note that, in a case where the light shielding film 13 is formed of a conductive material, a back gate effect can be imparted to the TFT by applying a predetermined electric potential to the light shielding film 13.

The A TFT is formed on the undercoat layer 12. An example of the TFT includes a polysilicon TFT using polysilicon for the semiconductor layer SC. However, the semiconductor layer SC is not limited to polysilicon, and may be an oxide semiconductor or amorphous silicon. In the present embodiment, the semiconductor layer SC is formed of low temperature polysilicon. As the TFT, either an NchTFT or a PchTFT may be used. Further, the NchTFT and the PchTFT may be formed simultaneously. Hereinafter, a case where the NchTFT is used as a TFT will be described.

The semiconductor layer SC of the NchTFT includes a first region, a second region, a channel region between the first region and the second region, and low-concentration impurity regions provided between the channel region and the first region and between the channel region and the second region. One of the first region and the second region functions as a source region, and the other functions as a drain region.

A gate insulating film GI is made of a silicon oxide film, and a gate electrode GE is made of MoW (molybdenum/tungsten). The gate electrode GE has not only a function as a gate electrode of the TFT but also a function as a storage capacitance electrode described later. Although the top-gate type TFT is exemplified here, the TFT may be a bottom-gate type TFT.

A passivation layer 14 is provided on the gate insulating film GI and the gate electrode GE. The passivation layer 14 is formed by sequentially stacking, for example, a silicon nitride film and a silicon oxide film on the gate insulating film GI and the gate electrode GE.

A first electrode E1 and a second electrode E2 of the TFT are provided on the passivation layer 14. Each of the first electrode E1 and the second electrode E2 has a three-layer stacked structure (Ti-based/Al-based/Ti-based), and includes a lowermost layer made of a metal material containing Ti (titanium) as a main component, such as Ti or an alloy containing Ti, a middle layer made of a metal material containing Al as a main component, such as Al (aluminum) or an alloy containing Al, and an uppermost layer made of a metal material containing Ti as a main component, such as Ti or an alloy containing Ti.

The first electrode E1 is connected to the first region of the semiconductor layer SC, and the second electrode E2 is connected to the second region of the semiconductor layer SC. For example, when the first region of the semiconductor layer SC functions as a drain region, the first electrode E1 is a drain electrode, and the second electrode E2 is a source electrode. The first electrode E1 forms a holding capacitor together with the passivation layer 14 and the gate electrode GE (holding capacitance electrode) of the TFT.

A planarizing film 15 is provided on the passivation layer 14, the first electrode E1, and the second electrode E2. The planarizing film 15 is removed in a region where the lower electrode E3 of the sensor 2 and the TFT are in contact with each other, and has an opening portion OP1. As the planarizing film 15, an organic insulating material such as photosensitive acrylic is often used. This is excellent in coverage of a conductive line step and surface flatness as compared with an inorganic insulating material formed by chemical vapor deposition or the like.

In the light receiving region A1, a lower electrode E3 of the sensor 2 is provided on the planarizing film 15. The lower electrode E3 is connected to the first electrode E1 through the opening portion OP1 formed in the planarizing film 15.

The planarizing film 15 and the lower electrode E3 are covered with the inorganic insulating film 16. The inorganic insulating film 16 is removed in a region where the organic photoreceiver OPD and the lower electrode E3 are in contact with each other, and has an opening. The inorganic insulating film 16 is formed of, for example, a silicon nitride film.

The lower electrode E3 and the inorganic insulating film 16 are covered with an organic photoreceiver OPD including a plurality of layers. In the light receiving region A1, the lower electrode E3 of the sensor 2 is in contact with the organic photoreceiver OPD at the opening formed in the inorganic insulating film 16.

Since the organic photoreceiver OPD cannot withstand a high-temperature process, it is desirable that the organic photoreceiver OPD be formed after a light emitting element LED to be described later is mounted. At this time, the organic photoreceiver OPD exposes the upper surface (emission surface) of the light emitting element LED.

An upper electrode E4 is provided on the organic photoreceiver OPD so as to cover the organic photoreceiver OPD. The upper electrode E4 is disposed not only in the light receiving region A1 but also in the light emitting region A2 and the conductive line region A3. The upper electrode E4 is required to be formed as a transparent electrode in order to receive light emitted from the light emitting element LED and transmitted through the finger Fg, and is formed using, for example, indium tin oxide (ITO).

The cross-sectional structure of the biometric authentication device 1 (sensor 2) in the light receiving region A1 is described above.

Next, a cross-sectional structure of the biometric authentication device 1 (illumination device 3) in the light emitting region A2 will be described. Note that description of portions similar to the cross-sectional structure in the light receiving region A1 will be omitted.

In the light emitting region A2, a power supply conductive line PL is provided on the passivation layer 14. The power supply conductive line PL is covered with the planarizing film 15. A lower electrode E5 of the illumination device 3 is provided on the planarizing film 15. The lower electrode E5 is connected to the power supply conductive line PL through the opening portion OP2 formed in the planarizing film 15. The lower electrode E5 is covered with the inorganic insulating film 16.

The inorganic insulating film 16 is removed in a region where a connection conductive member SO and the lower electrode E5 are in contact with each other, and has an opening. The connection conductive member SO is provided in the opening formed in the inorganic insulating film 16 and on the lower electrode E5. A light emitting element LED is provided on the connection conductive member SO. It is desirable that the light emitting element LED is a type of light source that emits light only in the immediately upward direction and does not emit light in the lateral direction. As described above, the upper surface of the light emitting element LED is exposed.

The upper electrode E4 provided in common in the regions A1, A2, and A3 is disposed on the light emitting element LED. As described above, since the upper electrode E4 is formed as a transparent electrode, light from the light emitting element LED can be extracted.

The cross-sectional structure of the biometric authentication device 1 (illumination device 3) in the light emitting region A2 is described above.

The conductive line region A3 will be described later and will not be described in detail here, but as shown in FIG. 3, a plurality of openings (through holes) penetrating from the passivation layer 14 to the surface of the support body 10 is formed, and a plurality of line portions LP is provided in the conductive line region A3. The line portion LP has a structure in which the base 11, the undercoat layer 12, the gate insulating film GI, the passivation layer 14, and the conductive line L are stacked in this order from the base 11 side, and is covered with the planarizing film 15.

A sealing layer 17 is provided on the upper electrode E4 disposed in the regions A1, A2, and A3. The sealing layer 17 is provided to suppress entry of moisture into the organic photoreceiver OPD from the outside. The sealing layer 17 has a stacked structure of an organic insulating film 18 and a pair of inorganic insulating films 19 sandwiching the organic insulating film. A resin layer 20 functioning as a protective film is provided on the sealing layer 17.

Although not illustrated in FIG. 3, the power supply conductive line for supplying power to the upper electrode E4 is provided, for example, in the same layer as the first electrode E1, the second electrode E2, the power supply conductive line PL, and the conductive line L. A plurality of the power supply conductive lines may be provided for each first pixels PX1 and each second pixels PX2, or only one power supply conductive line may be provided so as to be shared by all the pixels. However, in a case where only one power supply conductive line is provided so as to be shared by all the pixels, a voltage applied to a pixel that is farther from the power supply conductive line decreases due to the voltage drop based on the resistance of the upper electrode E4. For this reason, it is desirable that the power supply conductive line for supplying power to the upper electrode E4 is provided for each pixel. In this case, resistance can be reduced as compared with a case where the power supply conductive line is shared by all the pixels.

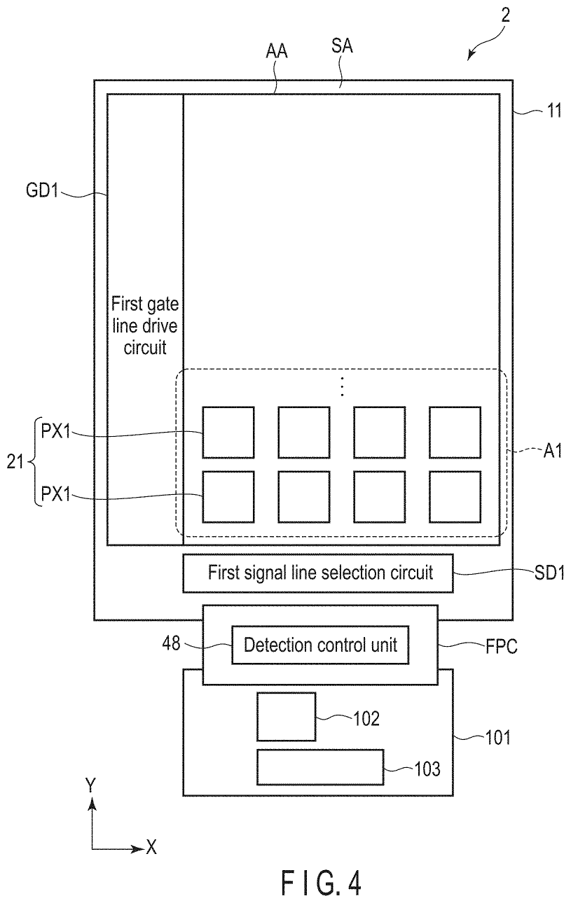

FIG. 4 is a plan view schematically illustrating a configuration of the sensor 2 included in the biometric authentication device 1. As illustrated in FIG. 4, the sensor 2 includes the base 11, a sensor unit 21 including a plurality of first pixels PX1 provided in the light receiving region A1, a first gate line drive circuit GD1, a first signal line selection circuit SD1, a detection circuit 48, a first control circuit 102, and a first power supply circuit 103. The first gate line drive circuit GD1 may be referred to as a sensor gate line drive circuit, the first signal line selection circuit SD1 may be referred to as a sensor signal line selection circuit, the first control circuit 102 may be referred to as a sensor control circuit, and the first power supply circuit 103 may be referred to as a sensor power supply circuit.

A control board 101 is electrically connected to the base 11 via the flexible printed circuit board FPC. The flexible printed circuit board FPC is provided with the detection circuit 48. The control board 101 is provided with the first control circuit 102 and the first power supply circuit 103.

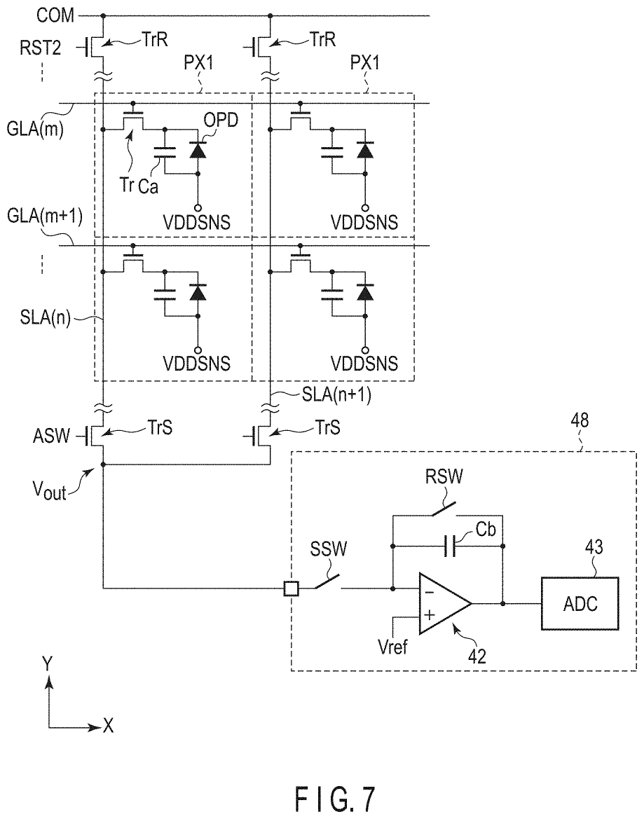

The first control circuit 102 is, for example, a field programmable gate array (FPGA). The first control circuit 102 supplies a control signal to the sensor unit 21, the first gate line drive circuit GD1, and the first signal line selection circuit SD1 to control the detection operation of the sensor unit 21. The first power supply circuit 103 supplies a voltage signal such as sensor power supply signal VDDSNS (see FIG. 7) to the sensor unit 21, the first gate line drive circuit GD1, and the first signal line selection circuit SD1.

The first gate line drive circuit GD1 and the first signal line selection circuit SD1 are provided in the peripheral region SA. For example, the first gate line drive circuit GD1 is provided in a region extending along the second direction Y in the peripheral region SA. The first signal line selection circuit SD1 is provided in a region extending along the first direction X in the peripheral region SA, and is provided between the sensor unit 21 and the detection circuit 48. However, positions of the first gate line drive circuit GD1 and the first signal line selection circuit SD1 are not limited to the above positions, and may be any position in the peripheral region SA.

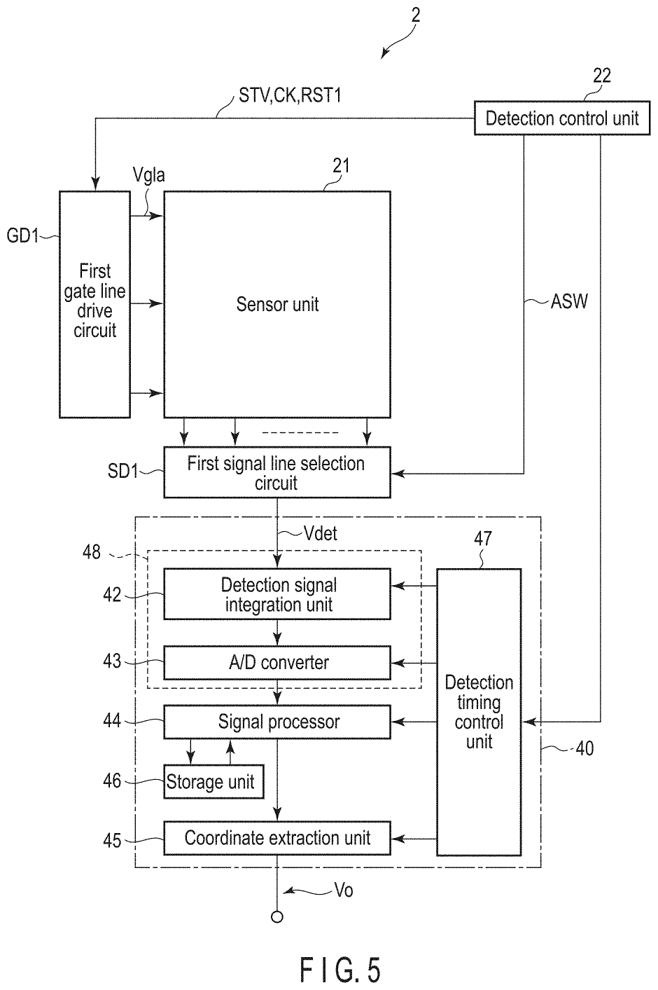

FIG. 5 is a block diagram illustrating a configuration example of the sensor 2 included in the biometric authentication device 1. As illustrated in FIG. 5, the sensor 2 further includes a detection control unit 22 and a detection unit 40. Some or all of the functions of the detection control unit 22 are included in the first control circuit 102. Some or all of the functions of the detection unit 40 other than detection circuit 48 are included in first control circuit 102.

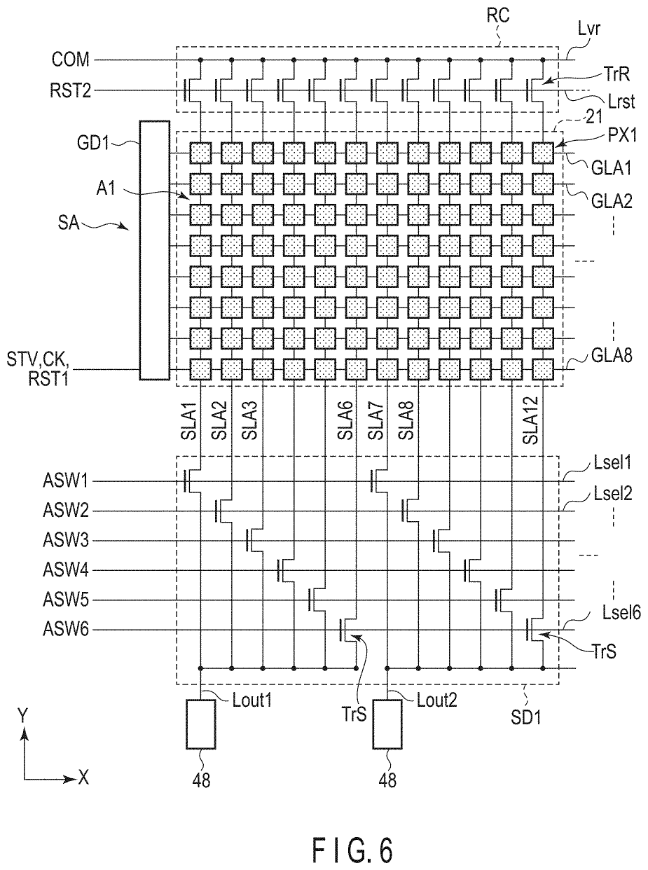

The sensor unit 21 is an optical sensor including an organic photoreceiver OPD which is a photoelectric conversion element. The organic photoreceiver OPD included in the sensor unit 21 outputs an electrical signal corresponding to the amount of received light to the first signal line selection circuit SD1. The first signal line selection circuit SD1 sequentially selects the signal line SLA (see FIG. 6) according to a selection signal ASW from the detection control unit 22. As a result, the above-described electrical signal is output to the detection unit 40 as the detection signal Vdet via the first signal line selection circuit SD1. In addition, the sensor unit 21 performs detection in accordance with a gate drive signal Vgla supplied from the first gate line drive circuit GD1.

The detection control unit 22 is a circuit that supplies a control signal to each of the first gate line drive circuit GD1, the first signal line selection circuit SD1, and the detection unit 40 to control operations of them. The detection control unit 22 supplies various control signals such as a start signal STV, a clock signal CK, and a reset signal RST1 to the first gate line drive circuit GD1. In addition, the detection control unit 22 supplies various control signals such as a selection signal ASW to the first signal line selection circuit SD1.

The first gate line drive circuit GD1 drives the plurality of gate lines GLA (see FIG. 6) based on various control signals. The first gate line drive circuit GD1 sequentially or simultaneously selects the plurality of gate lines GLA, and supplies a gate drive signal Vgla to the selected gate line GLA. Consequently, first gate line drive circuit GD1 selects the plurality of organic photoreceivers OPD connected to the gate lines GLA.

The first signal line selection circuit SD1 is a switch circuit that sequentially or simultaneously selects a plurality of signal lines SLA (see FIG. 6). The first signal line selection circuit SD1 is, for example, a multiplexer. The first signal line selection circuit SD1 connects the selected signal line SLA and the detection circuit 48 based on the selection signal ASW supplied from the detection control unit 22. As a result, the first signal line selection circuit SD1 outputs a detection signal Vdet from the organic photoreceiver OPD to the detection unit 40.

The detection unit 40 includes the detection circuit 48, a signal processor 44, a coordinate extraction unit 45, a storage unit 46, and a detection timing control unit 47. The detection timing control unit 47 causes the detection circuit 48, the signal processor 44, and the coordinate extraction unit 45 to operate in synchronization with each other based on the control signal supplied from the detection control unit 22.

The detection circuit 48 is, for example, an analog front end (AFE) circuit. The detection circuit 48 is, for example, a signal processing circuit including a detection signal integration unit 42 and an A/D converter 43. The detection signal integration unit 42 integrates the detection signal Vdet. The A/D converter 43 converts the analog signal output from the detection signal integration unit 42 into a digital signal. Note that, in the following description, a signal integrated by the detection signal integration unit 42 and converted from an analog signal to a digital signal by the A/D converter 43 to be output may be referred to as a detection signal Vdet.

The signal processor 44 is a logic circuit that detects a predetermined physical quantity input to the sensor unit 21 based on an output signal of the detection circuit 48. When the finger Fg comes into contact with or approaches the detection region AA, the signal processor 44 can detect the unevenness (that is, the fingerprint) of the surface of the finger Fg based on the output signal from the detection circuit 48.

The storage unit 46 temporarily stores the signal calculated by the signal processor 44. The storage unit 46 may be, for example, a random access memory (RAM), a register circuit, or the like.

The coordinate extraction unit 45 is a logic circuit that obtains detection coordinates of the unevenness of the surface of the finger Fg or the like when the contact or the approach of the finger Fg is detected by the signal processor 44. The coordinate extraction unit 45 combines the detection signals Vdet output from the organic photoreceivers OPD of the sensor unit 21 to generate two-dimensional information (for example, an image or the like) indicating the shape of the unevenness (that is, the fingerprint) of the surface of the finger Fg or the shape of the blood vessel pattern of the finger Fg. This two-dimensional information is biological information of the user.

Note that the coordinate extraction unit 45 may output the detection signal Vdet as the sensor output Vo without calculating the detection coordinates. In this case, the detection signal Vdet may be referred to as biological information of the user. Alternatively, the coordinate extraction unit 45 may output information (for example, pulse wave data or the like) regarding the living body that can be calculated based on the detection signal Vdet as the sensor output Vo without calculating the detection coordinates. In this case, information about the living body that can be calculated based on the detection signal Vdet may be referred to as biological information of the user.

Next, a circuit configuration example of the sensor 2 included in the biometric authentication device 1 will be described. FIG. 6 is a circuit diagram illustrating the sensor 2. FIG. 7 is a circuit diagram illustrating a plurality of first pixels PX1 included in the sensor 2. FIG. 7 also illustrates a circuit configuration of the detection circuit 48.

As illustrated in FIG. 6, the sensor unit 21 includes a plurality of first pixels PX1 disposed in a matrix. Each of the plurality of first pixels PX1 includes an organic photoreceiver OPD.

The gate line GLA extends in first direction X, and is connected to the plurality of first pixels PX1 arrayed in first direction X. The plurality of gate lines GLA1, GLA2, . . . , GLA8 is arrayed in second direction Y, and each connected to the first gate line drive circuit GD1. In the following description, the plurality of gate lines GLA1 to GLA8 is simply referred to as the gate line GLA when it is not necessary to distinguish the plurality of gate lines GLA1 to GLA8. Although eight gate lines GLA are illustrated in FIG. 6 for easy understanding of the description, it is merely an example, and M (M is 8 or more, for example, M=256) gate lines GLA may be disposed.

The signal line SLA extends in the second direction Y and is connected to the organic photoreceivers OPD of each of the plurality of first pixels PX1 disposed in the second direction Y. In addition, the plurality of signal lines SLA1, SLA2, . . . , and SLA 12 is disposed in the first direction X and each connected to the first signal line selection circuit SD1 and a reset circuit RC. Note that, in the following description, in a case where it is not necessary to distinguish and describe the plurality of signal lines SLA1 to SLA 12, they are simply referred to as the signal line SLA. In addition, although 12 signal lines SLA are illustrated in FIG. 6 for easy understanding of the description, it is merely an example, and N (N is 12 or more, for example, N=252) signal lines SLA may be disposed.

In FIG. 6, the sensor unit 21 is provided between the first signal line selection circuit SD1 and the reset circuit RC, but the present invention is not limited thereto, and the first signal line selection circuit SD1 and the reset circuit RC may be connected to the end of the signal line SLA in the same direction.

The first gate line drive circuit GD1 receives various control signals such as the start signal STV, the clock signal CK, and the reset signal RST1 from the first control circuit 102. The first gate line drive circuit GD1 sequentially selects the plurality of gate lines GLA1 to GLA8 in a time division manner based on various control signals. The first gate line drive circuit GD1 supplies the gate drive signal Vgla to the selected gate line GLA. As a result, the gate drive signal Vgla is supplied to the plurality of switching elements Tr connected to the gate line GLA, and the plurality of first pixels PX1 disposed in the first direction X is selected as a target for acquiring the detection signal Vdet.

The first gate line drive circuit GD1 may perform different driving for each detection mode of the fingerprint detection and the plurality of different pieces of biological information (for example, a pulse wave, a pulse, a blood vessel image, a blood oxygen concentration, and the like).

The first signal line selection circuit SD1 includes a plurality of selection signal lines Lsel, a plurality of output signal lines Lout, and a plurality of switching elements TrS. The plurality of switching elements TrS is provided corresponding to the plurality of respective signal lines SLA. The six signal lines SLA1 to SLA6 are connected to a common output signal line Lout1. The six signal lines SLA7 to SLA 12 are connected to a common output signal line Lout2. The output signal lines Lout1 and Lout2 are each connected to the detection circuit 48.

Here, the signal lines SLA1 to SLA6 are referred to as a first signal line block, and the signal lines SLA7 to SLA 12 are referred to as a second signal line block. The plurality of selection signal lines Lsel is connected to the gates of the switching elements TrS included in one signal line block. One selection signal line Lsel is connected to the gates of the switching elements TrS of the plurality of signal line blocks.

Specifically, the selection signal lines Lsel1 to Lsel6 are connected to the switching elements TrS corresponding to the signal lines SLA1 to SLA6, respectively. In addition, the selection signal line Lsel1 is connected to the switching element TrS corresponding to the signal line SLA1 and the switching element TrS corresponding to the signal line SLA7. The selection signal line Lsel2 is connected to the switching element TrS corresponding to the signal line SLA2 and the switching element TrS corresponding to the signal line SLA8.

The first control circuit 102 sequentially supplies the selection signal ASW to the selection signal line Lsel. As a result, the first signal line selection circuit SD1 sequentially selects the signal lines SLA in a time division manner in one signal line block by the operation of the switching elements TrS. In addition, the first signal line selection circuit SD1 selects one signal line SLA for each of the plurality of signal line blocks. With such a configuration, the sensor 2 can reduce the number of integrated circuits (ICs) including the detection circuit 48 or the number of terminals of the ICs.

Note that, although the case where the six signal lines SLA are connected to one output signal line Lout to form one signal line block has been exemplified here, it is possible to arbitrarily set how many signal lines SLA are connected to one output signal line Lout to form one signal line block. For example, four signal lines SLA may be connected to one output signal line Lout to form one signal line block.

As illustrated in FIG. 6, the reset circuit RC includes a reference signal line Lvr, a reset signal line Lrst, and switching elements TrR. The switching elements TrR are provided corresponding to the plurality of signal lines SLA. The reference signal line Lvr is connected to one of the source and the drain of each of the plurality of switching elements TrR. The reset signal line Lrst is connected to the gate of each of the plurality of switching elements TrR.

The first control circuit 102 supplies a reset signal RST2 to the reset signal line Lrst. As a result, the plurality of switching elements TrR is turned on, and the plurality of signal lines SLA is electrically connected to the reference signal line Lvr. The first power supply circuit 103 supplies a reference signal COM to the reference signal line Lvr. As a result, the reference signal COM is supplied to the capacitive element Ca included in each of the plurality of first pixels PX1.

As illustrated in FIG. 7, the first pixel PX1 includes the organic photoreceiver OPD, the capacitive element Ca, and the switching element Tr. FIG. 7 illustrates two gate lines GLA(m) and GLA(m+1) disposed in the second direction Y among the plurality of gate lines GLA. Further, two signal lines SLA(n) and SLA(n+1) disposed in the first direction X among the plurality of signal lines SLA are illustrated. The first pixel PX1 is disposed in a region surrounded by the gate line GLA and the signal line SLA. The switching element Tr is provided corresponding to the organic photoreceiver OPD. The switching element Tr includes a thin film transistor, and in this example, the switching element Tr includes an n-channel metal oxide semiconductor (MOS) type thin-film transistor (TFT).

The gates of the switching elements Tr belonging to the plurality of first pixels PX1 arranged in the first direction X are connected to the gate line GLA. The sources of the switching elements Tr belonging to the plurality of first pixels PX1 arranged in the second direction Y are connected to the signal line SLA. The drain of the switching element Tr is connected to the cathode of the organic photoreceiver OPD and the capacitive element Ca.

A sensor power supply signal VDDSNS is supplied from the first power supply circuit 103 to the anode of the organic photoreceiver OPD. In addition, the reference signal COM serving as an initial electric potential of the signal line SLA and the capacitive element Ca is supplied from the first power supply circuit 103 to the signal line SLA and the capacitive element Ca.

When light is received at the first pixel PX1, a current corresponding to the amount of light flows through the organic photoreceiver OPD included in the first pixel PX1. As a result, a charge is accumulated in the capacitive element Ca. When the switching element Tr is turned on, a current flows through the signal line SLA according to the charge accumulated in the capacitive element Ca. The signal line SLA is connected to the detection circuit 48 via the switching element TrS of the first signal line selection circuit SD1. As a result, the sensor 2 can detect a signal corresponding to the amount of light to be received by the organic photoreceiver OPD for each first pixel PX1.

The detection circuit 48 is connected to the signal line SLA with the switch SSW turned on in the read period. The detection signal integration unit 42 of the detection circuit 48 integrates the current supplied from the signal line SLA, converts the current into a voltage, and output the voltage. A reference electric potential (Vref) having a fixed electric potential is input to the non-inverting input unit (+) of the detection signal integration unit 42, and the signal line SLA is connected to the inverting input terminal (−). Here, the same signal as the reference signal COM is input as the reference electric potential (Vref). In addition, the detection signal integration unit 42 includes a capacitive element Cb and a reset switch RSW. In a reset period after the read period, the reset switch RSW is turned on, and the charge of the capacitive element Cb is reset.

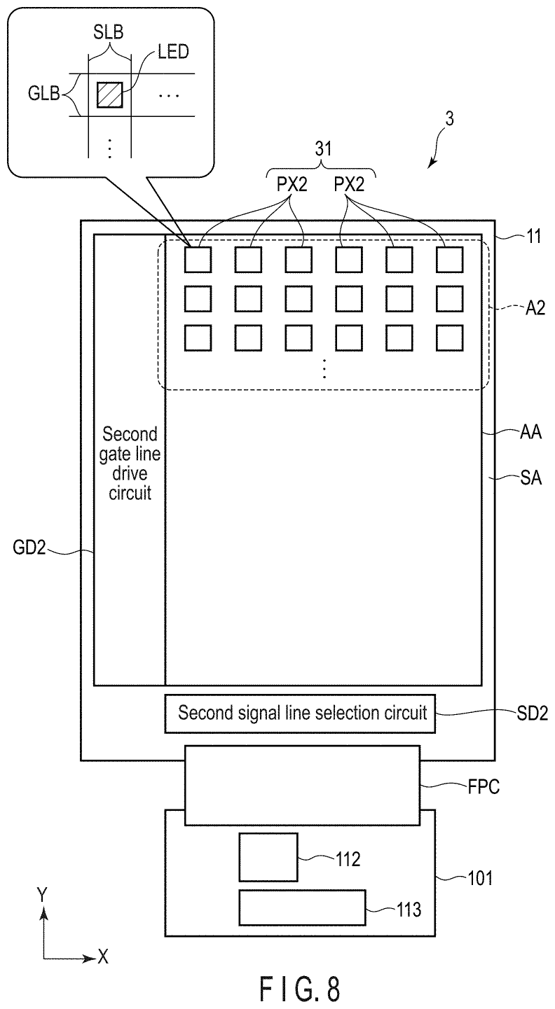

Next, the illumination device 3 included in the biometric authentication device 1 will be described. FIG. 8 is a plan view schematically illustrating a configuration of the illumination device 3 included in biometric authentication device 1. In FIG. 8, only elements related to the illumination device 3 are illustrated, and elements related to the sensor 2 are not illustrated. As illustrated in FIG. 8, illumination device 3 includes a light emitting unit 31 including a plurality of second pixels PX2 provided in the light emitting region A2, a second gate line drive circuit GD2, a second signal line selection circuit SD2, a second control circuit 112, and a second power supply circuit 113. The second gate line drive circuit GD2 may be referred to as a light source gate line drive circuit, the second signal line selection circuit SD2 may be referred to as a light source signal line selection circuit, the second control circuit 112 may be referred to as a light source control circuit, and the second power supply circuit 113 may be referred to as a light source power supply circuit.

The second control circuit 112 and the second power supply circuit 113 are provided on the control board 101 electrically connected to the base 11 via the flexible printed circuit board FPC. The control circuit 112 is, for example, an FPGA. The control circuit 112 supplies a control signal to the light emitting unit 31, the second gate line drive circuit GD2, and the second signal line selection circuit SD2 to control the lighting operation of the light emitting element LED of each of the plurality of second pixels PX2 included in the light emitting unit 31. The second power supply circuit 113 supplies a voltage signal such as a light source power supply signal to the light emitting unit 31, the second gate line drive circuit GD2, and the second signal line selection circuit SD2.

The second gate line drive circuit GD2 and the second signal line selection circuit SD2 are provided in the peripheral region SA. In FIG. 8, the second gate line drive circuit GD2 is provided in a region extending along the second direction Y in the peripheral region SA, and the second signal line selection circuit SD2 is provided in a region extending along the first direction X in the peripheral region SA. However, the present invention is not limited thereto, and the second gate line drive circuit GD2 and the second signal line selection circuit SD2 may be disposed at any positions in the peripheral region SA.

The second gate line drive circuit GD2 is a circuit that drives the plurality of gate lines GLB based on various control signals. The second gate line drive circuit GD2 sequentially or simultaneously selects the plurality of gate lines GLB, and supplies the gate drive signal to the selected gate lines GLB. Consequently, the second gate line drive circuit GD2 selects the plurality of light emitting elements LED connected to the gate line GLB.

The second signal line selection circuit SD2 is a switch circuit that sequentially or simultaneously selects a plurality of signal lines SLB. The second signal line selection circuit SD2 is, for example, a multiplexer. The second signal line selection circuit SD2 sequentially or simultaneously selects the plurality of signal lines SLB and supplies a selection signal to the selected signal lines SLB. As a result, the second signal line selection circuit SD2 selects one or a plurality of light emitting elements LED among the plurality of light emitting elements LED selected by the second gate line drive circuit GD2.

As illustrated in FIG. 8, the light emitting element LED of the second pixel PX2 is disposed in a region surrounded by the gate line GLB and the signal line SLB. Each of the light emitting elements LED is connected to the gate line GLB extending along the first direction X and disposed with an interval in the second direction Y, and the signal line SLB extending along the second direction Y and disposed with an interval in the first direction X. Although described in detail later, the signal line SLB may extend to the conductive line region A3. As described above, the light emitting element LED is selectively turned on by the control signal supplied from the second gate line drive circuit GD2 and the second signal line selection circuit SD2.

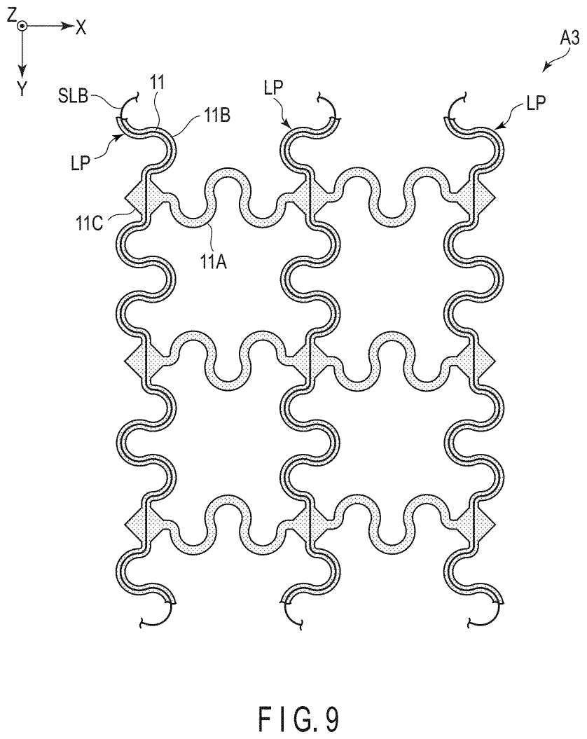

Next, the conductive line region A3 will be described with reference to FIG. 9.

As described above, the conductive line region A3 is a region interposed between the light receiving region A1 and the light emitting region A2. The conductive line region A3 is a region curved along the side face of the finger Fg when the biometric authentication device 1 is wound around the finger Fg to be detected. For this reason, the conductive line region A3 desirably has a stretchable structure. Note that, when the conductive line region A3 has a stretchable structure, position adjustment of the light receiving region A1 and the light emitting region A2 when the biometric authentication device 1 is wound around the finger Fg can be performed by extending and contracting the conductive line region A3. That is, when the biometric authentication device 1 is wound around the finger Fg, it is possible to easily perform position adjustment for positioning the light receiving region A1 so as to be in contact with the lower face of the finger Fg and positioning the light emitting region A2 so as to be in contact with the upper face of the finger Fg.

As illustrated in FIG. 9, in the conductive line region A3, the base 11 is formed to have a plurality of first portions 11A extending in a wave shape in the first direction X and disposed side by side in the second direction Y, a plurality of second portions 11B extending in a wave shape in the second direction Y and disposed side by side in the first direction X, and a plurality of island-shaped portions 11C (third portions) located at intersections of the first portions 11A and the second portions 11B. That is, in the conductive line region A3, the base 11 is formed so as to have an opening in a region surrounded by the first portion 11A, the second portion 11B, and the island-shaped portion 11C. This opening corresponds to an opening penetrating from the passivation layer 14 to the surface of the support body 10 illustrated in FIG. 3. By disposing the island-shaped portion 11C at the intersection between the first portion 11A and the second portion 11B, it is possible to disperse the stress when being pulled and to prevent the base 11 from being broken in the conductive line region A3.

As illustrated in FIG. 9, in the conductive line region A3, the signal line SLB connected to the second pixel PX2 disposed in the light emitting region A2 is disposed on the second portion 11B formed in a wave shape. Note that, although FIG. 9 illustrates the configuration in which the signal line SLB is disposed on the second portion 11B, the conductive line disposed in the conductive line region A3 is not limited to the signal line SLB, and for example, any conductive line such as a power supply conductive line for supplying a voltage to the lower electrode E5 or the upper electrode E4 of the light emitting element LED included in the second pixel PX2 may be disposed on the first portion 11A or the second portion 11B. Alternatively, the base 11 may only have a stretchable structure without any conductive line disposed on the first portion 11A and the second portion 11B.

As described above, since the conductive line region A3 has a stretchable structure, the length of the conductive line region A3 in the second direction Y in the natural state in which the conductive line region A3 is not stretched may be shorter than the length of the light receiving region A1 in the second direction Y or the length of the light emitting region A2 in the second direction Y.

According to the first embodiment described above, the biometric authentication device 1 includes the sensor 2 and the illumination device 3 disposed on the same substrate, and the light receiving region A1 in which the sensor 2 is disposed and the light emitting region A2 in which the illumination device 3 is disposed do not overlap each other in planar view and are disposed separately by the conductive line region A3 interposed between the light receiving region A1 and the light emitting region A2. The conductive line region A3 has a stretchable structure. Accordingly, it is possible to provide the biometric authentication device 1 that can be wound around the finger Fg to be detected and can detect the biological information from the finger Fg.

In addition, since the sensor 2 and the illumination device 3 are disposed on the same substrate, the number of flexible printed circuit boards FPC connected to the base 11 can be reduced to one. Therefore, it is possible to provide the biometric authentication device 1 (that is, biometric authentication device 1 having a compact shape) that is downsized as compared with a general configuration in which the sensor 2 and the illumination device 3 are disposed on different substrates and the number of flexible printed circuit boards is same as the number of substrates.

Furthermore, since the biometric authentication device 1 has a stretchable structure in the conductive line region A3 as described above, position adjustment of the light receiving region A1 and the light emitting region A2 when the biometric authentication device 1 is wound around the finger Fg to be detected can be easily performed by expanding and contracting the conductive line region A3.

In addition, since the biometric authentication device 1 can be used by being wound around the finger Fg to be detected as described above, the distance from the illumination device 3 to the sensor 2 can be shortened as compared with the general configuration described above, and the utilization efficiency of the light emitted from the illumination device 3 can be improved.

In the present embodiment, since it is assumed that the sensor 2 is disposed toward the flexible printed circuit board FPC and the illumination device 3 is disposed away from the flexible printed circuit board FPC, the signal line SLB connected to the second pixel PX2 included in the illumination device 3 is disposed in the conductive line region A3, but the present invention is not limited thereto. The illumination device 3 may be disposed toward the flexible printed circuit board FPC and the sensor 2 may be disposed away from the flexible printed circuit board FPC, and any conductive line connected to the first pixel PX1 included in the sensor 2 may be disposed in the conductive line region A3.

### Second Embodiment

Next, a second embodiment will be described. The second embodiment is different from the first embodiment described above in that an illumination device 3 is disposed so as to surround a sensor 2. Hereinafter, description of the configuration same as that of the first embodiment will be omitted, and differences from the first embodiment will be mainly described.

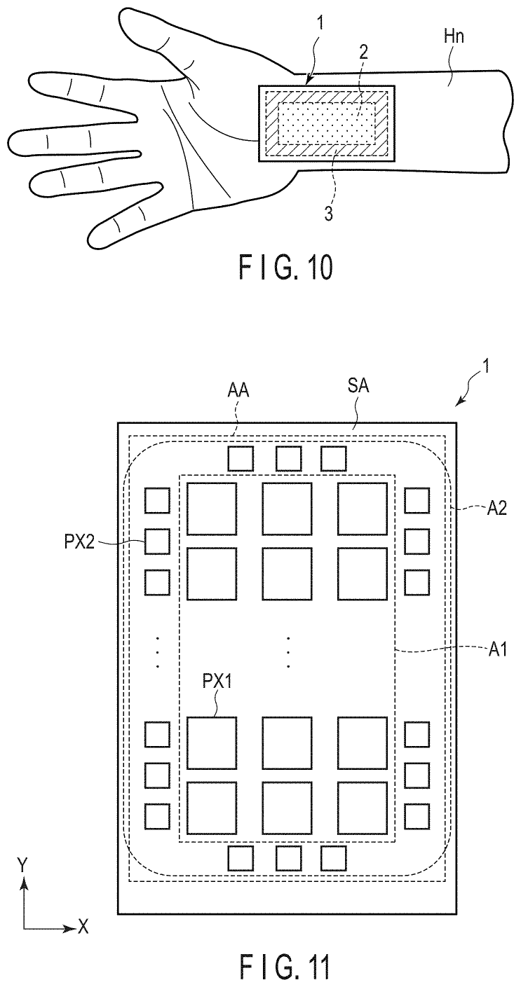

FIG. 10 is a schematic diagram illustrating a schematic configuration of a biometric authentication device 1 according to the second embodiment. As illustrated in FIG. 10, the biometric authentication device 1 is used in contact with a wrist Hn, for example. The biometric authentication device 1 includes a sensor 2 and an illumination device 3 posed on the same substrate, and the illumination device 3 is disposed so as to surround the sensor 2.

The light emitted from the illumination device 3 is reflected by the wrist Hn and detected by the sensor 2. The sensor 2 is a reflective type optical sensor, and can detect biological information of the wrist Hn by detecting light reflected by the wrist Hn. In the present embodiment, it is assumed that the detection target is the wrist Hn, but the detection target is not limited thereto, and any part having a face that can be in contact with the sensor 2 and the illumination device 3 can be the detection target.

FIG. 11 is a plan view illustrating an example of an arrangement layout of the sensor 2 and the illumination device 3 included in the biometric authentication device 1. As illustrated in FIG. 11, the biometric authentication device 1 includes a base 11, and a detection region AA and a peripheral region SA provided on the base 11. The detection region AA includes a light receiving region A1 and a light emitting region A2. As illustrated in FIG. 11, the light receiving region A1 and the light emitting region A2 included in the detection region AA do not overlap each other in planar view.

The light receiving region A1 is a region in which a plurality of first pixels PX1 constituting the sensor 2 is provided, and the plurality of first pixels PX1 is disposed in a matrix in the first direction X and the second direction Y. The light emitting region A2 is a region in which the plurality of second pixels PX2 constituting the illumination device 3 is provided, and the plurality of second pixels PX2 is disposed so as to surround the light receiving region A1. In the present embodiment, the operation of the light emitting elements LED included in the plurality of second pixels PX2 may be individually controlled, or the operation may be collectively controlled.

Also in the second embodiment described above, the biometric authentication device 1 includes the sensor 2 and the illumination device 3 disposed on the same substrate, and the light receiving region A1 in which the sensor 2 is disposed and the light emitting region A2 in which the illumination device 3 is disposed do not overlap each other in planar view. As described above, since the sensor 2 and the illumination device 3 are disposed on the same substrate, the number of flexible printed circuit boards FPC connected to the base 11 can be reduced to one. Therefore, it is possible to downsize the biometric authentication device as compared with a general configuration in which the sensor 2 and the illumination device 3 are disposed on different substrates and the number of flexible printed circuit boards is same as the number of substrates, and it is possible to provide the biometric authentication device 1 having a compact shape.

In addition, in the biometric authentication device 1, since the illumination device 3 is disposed so as to surround the sensor 2 and the illumination device 3 can be disposed in the vicinity of the sensor 2, it is possible to improve the utilization efficiency of the light emitted from the illumination device 3.

According to at least one embodiment described above, the sensor 2 and the illumination device 3 can be provided on the same substrate, and the miniaturized biometric authentication device 1 can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A biometric authentication device comprising:
a resin substrate having flexibility;
an optical sensor disposed on the resin substrate; and
an illumination device disposed on the resin substrate, wherein
the optical sensor and the illumination device are disposed on the resin substrate so as to face each other with a detection target interposed therebetween when the biometric authentication device is mounted on the detection target, and
the optical sensor detects light emitted from the illumination device and transmitted through the detection target.

2. The biometric authentication device of claim 1, wherein
the optical sensor includes a plurality of first pixels disposed in a matrix on the resin substrate and each including an organic photoreceiver that outputs a signal corresponding to an amount of received light,
the illumination device includes a plurality of second pixels disposed in a matrix on the resin substrate and each including a light emitting element that emits light to be received by the organic photoreceiver, and
a third region in which the first pixel and the second pixel are not provided is disposed between a first region in which the first pixels is provided and a second region in which the second pixels is provided.

3. The biometric authentication device of claim 2, wherein the resin substrate has a stretchable structure in the third region.

4. The biometric authentication device of claim 3, further comprising:
a support body that supports the resin substrate, wherein
the resin substrate has, in the third region,
a plurality of first portions extending in a wave shape in a first direction and disposed side by side in a second direction intersecting the first direction,
a plurality of second portions extending in a wave shape in the second direction and disposed side by side in the first direction,
a plurality of third portions disposed at positions where the first portions and the second portions intersect with each other, and
openings penetrating to a surface of the support body in a region surrounded by the first portions, the second portions, and the third portions.

5. The biometric authentication device of claim 4, further comprising:
conductive lines disposed on each of the first portions or each of the second portions and connected to each of the first pixels or each of the second pixels.

6. The biometric authentication device of claim 5, wherein
the organic photoreceiver is formed in the first region, the second region, and the third region,
the organic photoreceiver is in contact with an electrode of each of the first pixels in the first region,
the organic photoreceiver covers a side face of a light emitting element of each of the second pixels in the second region, and
the organic photoreceiver overlaps conductive lines formed on the first portions or the second portions in the third region.

7. A biometric authentication device comprising:
a resin substrate having flexibility;
an optical sensor disposed on the resin substrate; and
an illumination device disposed on the resin substrate, wherein
the optical sensor and the illumination device are disposed on the resin substrate so as not to overlap each other in planar view,
the illumination device is disposed on the resin substrate so as to surround the optical sensor, and
the optical sensor detects light emitted from the illumination device and reflected by a detection target.
